(19) United States
(12) Patent Application Publication
(10) Pub. No.: US 2026/0179703 A1
(43) Pub. Date: Jun. 25, 2026

(54) MEMORY DEVICE

(71) Applicant: Taiwan Semiconductor Manufacturing Company, Ltd., Hsinchu (TW)

(72) Inventors: Yu-Wei LIN, Taichung City (TW); Meng-Sheng CHANG, Hsinchu (TW)

(21) Appl. No.: 19/092,670

(22) Filed: Mar. 27, 2025

Related U.S. Application Data
(60) Provisional application No. 63/737,253, filed on Dec. 20, 2024.

(51) Int. Cl. G11C 17/18; G11C 17/16

(52) U.S. Cl. CPC G11C 17/18; G11C 17/16

(57) ABSTRACT

A memory device and array architecture feature transmission gates and repeaters to enhance signal integrity and performance. The device includes multiple memory segments, each connected to a decoder through transmission gates, and a repeater circuit positioned along word lines. Memory cells within the segments can be eFuse cells in various configurations, including 2T/1R and 1T/1R. The repeaters, designed as two-stage inverters with PMOS and NMOS transistors, are strategically placed to ensure robust signal propagation. The memory array comprises multiple word and bit lines, with repeaters separating adjacent memory cells, and includes decoders for voltage level shifting. The architecture supports various threshold voltage repeaters, ensuring flexibility and efficiency in different operating conditions.

### CROSS-REFERENCE TO RELATED APPLICATIONS

This application claims the benefit of U.S. Provisional Application No. 63/737,253, filed on Dec. 20, 2024, the entire disclosure of which is incorporated herein by reference in its entirety.

### BACKGROUND

Many integrated circuits (ICs) are made up of millions of interconnected devices, such as transistors, resistors, capacitors, and diodes, on a single chip of semiconductor substrate. It is generally desirable that ICs operate as fast as possible, and consume as little power as possible. Semiconductor ICs often include one or more types of memory, such as complementary Metal-Oxide-Semiconductor (CMOS) memory, antifuse memory, and electrical fuse (eFuse) memory.

Electronic memory used in IC devices can be configured to store bits of data in respective memory cells. A memory cell is a circuit configured to store a bit of data, typically using one or more transistors. Memory may come in the form of Non-Volatile Memory (NVM). One type of NVM is one-time programmable (OTP) memory. Data in NVM is not lost when the IC is turned off. NVM allows an IC manufacturer to store a lot number and security data on the IC, for example, and is useful in many other applications.

One type of NVM utilizes an electrical fuse eFuse. EFuses are typically integrated into semiconductor ICs by using a narrow strip (commonly referred to as a “fuse link”) of conducting material (metal, poly-silicon, etc.) between two pads, generally referred to as anode and cathode. Applying a program current to the eFuse destroys (i.e., fuses) the link, thus changing the resistivity of the eFuse. This is commonly referred to as “programming” the eFuse. The eFuse link is sometimes referred to as a resistor in this specification as the resistivity of the eFuse changes in the programming process.

### BRIEF DESCRIPTION OF THE DRAWINGS

The accompanying drawings, which are incorporated in and constitute a part of the description, illustrate several aspects of the present disclosure. A brief description of the drawings is as follows:

FIGS. 1 and 2 show a memory device according to an embodiment.

FIGS. 3 and 4 show memory segments that can be used in the memory devices of FIGS. 1 and 2.

FIGS. 5-8 show memory cells usable in the memory segments of FIGS. 3 and 4.

FIG. 9 shows a repeater architecture according to one embodiment.

FIG. 10 shows a method flow usable for operating a memory device including word-line repeaters.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A two-transistor, one-resistor (2T(NMOS)1R) memory cell is a type of dynamic random-access memory (DRAM) cell, which leverages two N-channel Metal Oxide Semiconductor (NMOS) transistors and a single resistor to store a bit of information. In its basic configuration, the cell utilizes one NMOS transistor as the access transistor and another NMOS transistor as the storage transistor. The access transistor is connected to the word line (WL), which controls the access to the memory cell, while the storage transistor is connected to the bit line (BL), which serves as the data input/output line. The resistor, typically implemented as a high-resistance element, is used to maintain the charge on the storage capacitor, ensuring that the data is held for a longer duration despite the inherent leakage.

During a write operation, the word line is activated, turning on the access transistor and allowing the bit line to drive the storage node. A voltage corresponding to a logic ‘1’or ‘0’is applied to the bit line, which then charges or discharges the storage capacitor through the storage transistor. The resistor helps to stabilize the voltage at the storage node by providing a resistive path to the power supply or ground, which can aid in maintaining the stored charge. Once the word line is deactivated, the access transistor is turned off, isolating the storage node and capturing the charge that represents the stored bit.

In the read operation, the word line is again activated, turning on the access transistor and connecting the storage node to the bit line. The voltage on the storage node is then sensed by a sense amplifier connected to the bit line, which determines whether the stored bit is a ‘1’ or ‘0’ based on the detected voltage level. The resistor plays a crucial role during the read operation by helping to maintain the integrity of the stored charge, ensuring that the sensed voltage accurately reflects the stored data. However, due to the dynamic nature of the charge storage, the data in a 2T(NMOS)1R memory cell must be periodically refreshed to counteract leakage currents and preserve data integrity over time. This periodic refreshing is a characteristic requirement of DRAM technology, ensuring that the stored information remains accurate and reliable.

As described in the Background, eFuse is a type of NVM that is used in various IC devices. Such eFuse memory may include an array of eFuse memory cells arranged in rows and columns, which each column having a corresponding bit line (BL) and each row having a corresponding word line (WL). Larger arrays of eFuse memory can be useful for programming purposes, but come with tradeoffs inherent to IC design. Specifically, longer WL and/or BL path can lead to degraded programming performance. Longer WL and BL in memory circuits not only face increased resistance and capacitance but also encounter signal integrity challenges like voltage drop, noise, and crosstalk, which can disrupt proper data reading and writing. Higher power consumption is another consequence, as driving signals through longer lines requires more energy. Parasitic resistance may be higher along the BL, which can impede the flow of current, thereby affecting the efficiency and speed of programming the memory cells, having follow-on effects as described in more detail below. Variability in line characteristics across the array can lead to uneven performance, and reliability issues such as electromigration may arise, potentially degrading line integrity over time. Furthermore, the additional delay introduced by longer lines can impact the timing and speed of memory operations, thereby affecting overall system performance.

A larger memory device may therefore increase the program current, but comes at the cost of larger leakage in the WL path. As described above, a longer BL path can also result in higher parasitic resistance. In an Ultra-High Density (UHD) memory structure, the performance related to programming current (the current used to write data to memory cells) might be worse than in a typical memory structure. This degradation in performance is attributed to a higher parasitic resistance in the BL.

The Rₒₙ value of a program device refers to the on-resistance of the device when it is in the conducting state. In the context of memory circuitry, such as eFuse memory, the Rₒₙ value represents the resistance value of the programming device (such as a transistor) when it is turned on, allowing current to flow through it. A lower Rₒₙ value generally means that the device can conduct current more efficiently, leading to better performance during programming operations. Conversely, a higher Rₒₙ value indicates higher resistance when the device is conducting, which can impede current flow and potentially impact the programming performance of the memory.

As described in more detail with respect to the figures, a repeater circuit can be implemented on the WL, designed to amplify or restore the signal as it travels along the length of the WL. Due to the inherent resistance and capacitance of long conductive paths, signals can degrade as they propagate, leading to slower response times and potential errors in accessing memory cells. To address this issue, repeater circuits are strategically placed along the WL to ensure that the signal strength and integrity are maintained, enabling reliable and rapid access to memory cells located farther from the WL driver.

When a voltage signal is applied to a WL to activate a row of memory cells, the repeater circuit can detect this signal and regenerate it to its original amplitude. This involves amplifying the voltage level and possibly reshaping the signal to counteract any distortion that may have occurred during its travel. By doing so, the repeater ensures that the signal remains strong and clear enough to reliably turn on the access transistors of the memory cells along the entire length of the WL.

The placement and design of these repeaters are carefully optimized to balance the trade-offs between signal integrity, power consumption, and overall circuit complexity. By incorporating repeater circuits, memory designers can ensure that the word line signals remain robust, thereby enhancing the speed and accuracy of memory access operations across the entire array.

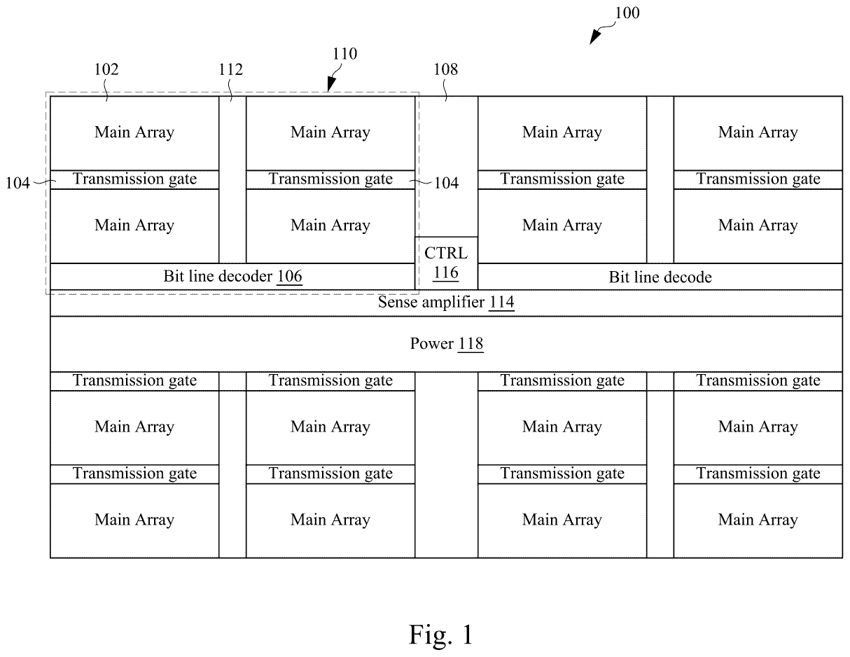

FIG. 1 shows a schematic layout of a circuit implementing a memory device 100 within the scope of the instant disclosure.

Memory device 100 includes first array 102, also referred to as a memory array, which is one main array amongst a larger set of main arrays. First array 102 is coupled to a first transmission gate 104. First transmission gate 104 is one of a large number of transmission gates 104, each corresponding to one or more main array.

A set of main arrays (e.g., first array 102) can be coupled via transmission gates 104 via a first decoder and a second decoder. In the embodiment of FIG. 1, first array 102 is connected to a shared bit line decoder 106 and a shared word line decoder 108 via the transmission gates 104. The combination of the set of main arrays that are coupled to the same bit line decoder 106 and the same word line decoder 108 are outlined as first memory segment 110. First memory segment 110 includes a main array 102, as well as a second array to the right thereof in FIG. 1 (coupled along the same word line), a third array below the main array 102 (connected along the same bit line), and a fourth array (not connected to main array 102 by any word or bit lines). In alternative embodiments, there may be any number of main arrays within a particular memory segment. There can also be any number of transmission gates 104. It is possible that multiple memory arrays (e.g., main array 102) can be coupled to adjacent memory arrays via dedicated transmission gates. Alternatively, a single transmission gate 104 can couple more than two memory arrays. That is, multiple transmission gates can be replaced by a single combined transmission gate.

FIG. 1 shows four memory segments (including first memory segment 110, a second memory segment in the upper-right quadrant, a third memory segment in the lower-left quadrant, and a fourth memory segment in the lower-right quadrant). In practice, there can be a plurality of memory segments in any particular device like memory device 100.

The four memory segments are each connected to a bit line decoder 106 and a word line decoder 108, each of which can also be referred to as a level shifter. In the context of a 2T(NMOS)1R memory cell, a decoder or level shifter (e.g., bit line decoder 106 and word line decoder 108) is a circuit component used to translate voltage levels between different parts of the memory circuit. This is used, for example, in scenarios where the memory cell operates at a different voltage level compared to the peripheral circuitry, such as the word line drivers or sense amplifiers. The level shifter ensures that signals are correctly interpreted and transmitted across these differing voltage domains, facilitating proper operation and data integrity within the memory cell.

Level shifters serve as components in memory circuits by enabling voltage translation between different domains of the circuit. In memory devices utilizing 2T(NMOS)1R cells, these components are used for ensuring proper communication between memory cells and their associated peripheral circuitry, such as those shown in memory device 100. The level shifter's primary purpose is to translate voltage signals between different parts of the memory circuit, particularly when the memory cell operates at a different voltage level compared to the peripheral circuitry, such as word line drivers or sense amplifiers.

The fundamental operation of a level shifter involves receiving an input signal at one voltage level and generating a corresponding output signal at another voltage level. This conversion process is vital for maintaining proper signal interpretation across different voltage domains within the memory architecture. For instance, when memory cells operate at a lower voltage than the peripheral logic circuits, the level shifter converts the lower voltage signals from the cells to higher voltage signals that are compatible with the peripheral logic, and vice versa. This conversion ensures that the correct logic levels are maintained and that transistors within both the memory cells and peripheral circuits switch appropriately.

In the context of memory operations, level shifters play a particularly important role during both read and write processes. During write operations, the level shifter adjusts the voltage levels of the signals that control the access transistor, ensuring it turns on or off correctly to enable proper data writing to the storage node. Similarly, during read operations, the level shifter adapts the sensed voltage levels from the storage node to ensure compatibility with the sense amplifier 114 and other readout circuitry.

The implementation of level shifters in memory architectures is especially critical when interfacing with word lines 120 and bit lines 122. These components work in conjunction with decoders, such as the bit line decoder 106 and word line decoder 108, to ensure proper voltage translation throughout the memory circuit. This voltage level adjustment is fundamental for maintaining signal integrity and ensuring reliable data transfer between different sections of the memory architecture.

The significance of level shifters extends beyond basic functionality to the overall reliability and efficiency of memory operations. By enabling different sections of the circuit to operate at their optimal voltage levels while maintaining proper communication between these sections, level shifters help prevent potential issues such as misinterpretation of data due to voltage mismatches. This capability is particularly important in modern memory architectures where power efficiency and reliable operation are paramount considerations.

In a 2T(NMOS)1R memory cell, the level shifter might be employed when driving the WL or when interfacing with the BL circuitry. During a write operation, the level shifter adjusts the voltage levels of the signals controlling the access transistor, ensuring that it turns on or off correctly to allow data to be written to the storage node. During a read operation, the level shifter adjusts the sensed voltage levels from the storage node to be compatible with the sense amplifier and other readout circuitry.

As described above, first memory segment 110 includes a set of word lines and bit lines. While generally speaking longer word lines and bit lines can provide advantages, there is the potential to lose functionality of the memory device 100 when there is significant loss of voltage or current due to parasitic loads. First memory segment 110 includes repeater 112, which sets the voltage of the word lines back to the desired voltage level at a midpoint of the word line. Although shown as a single repeater 112 at the center of the word lines, it should be understood that there could be one, two, or a plurality of repeaters 112 within first memory segment 110 or any others of the plurality of memory segments.

Controller 116 serves as a central management unit for coordinating operations across multiple components of memory device 100. Working in conjunction with power supply 118, controller 116 manages the operation of both word line decoder 108 and sense amplifier 114 to ensure proper memory access and data handling.

The controller 116 coordinates with word line decoder 108 to manage the voltage levels applied to word lines 120, which is particularly important when working with the repeaters 112 distributed throughout the memory segments 110. By controlling the word line decoder 108, controller 116 helps ensure that appropriate voltage levels are maintained along the word lines 120, even as the signals pass through multiple repeaters 112.

In terms of read operations, controller 116 works closely with sense amplifier 114 to accurately detect and interpret the stored data values. The controller 116 manages the timing and sequencing of operations between bit line decoder 106 and sense amplifier 114, ensuring proper coordination during memory access operations. This is particularly important when dealing with the various memory cell configurations supported by the device, including both 2T(NMOS)1R and 2T(PMOS)1R arrangements.

The controller 116's interaction with these components is especially critical during programming operations of the eFuse memory cells. When programming operations are performed, the controller 116 must ensure that appropriate program current is delivered through the bit lines 122 while maintaining proper word line activation through word line decoder 108. This coordination is essential for achieving reliable programming while managing the parasitic resistance and leakage concerns that can affect programming performance.

Through its management of both decoders and the sense amplifier 114, controller 116 helps maintain signal integrity across the memory segments 110, particularly in scenarios where multiple memory segments are connected through transmission gates 104. This comprehensive control ensures that memory operations remain reliable even in ultra-high density memory structures where parasitic resistance and signal degradation could otherwise impact performance.

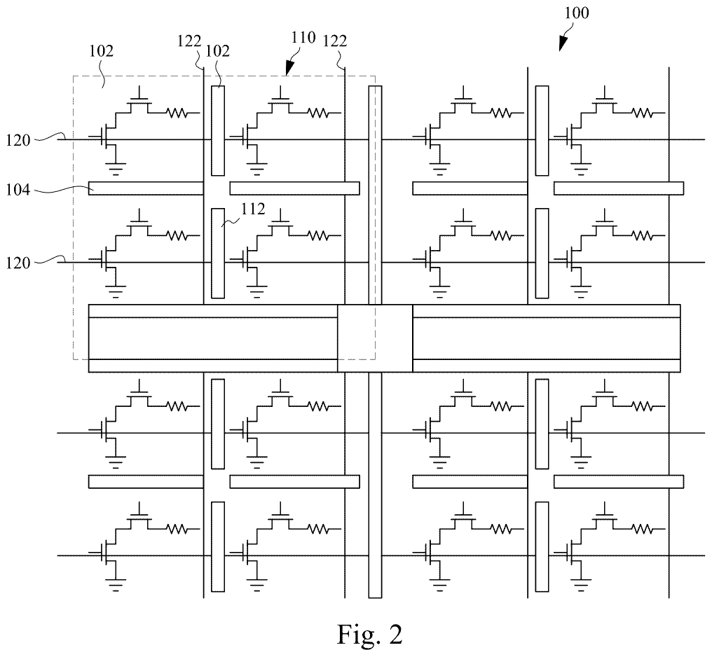

FIG. 2 is a schematic view of memory device 100 of FIG. 1, more specifically showing some of the electrical structures therein. In particular, FIG. 2 shows an array of 2-transistor, 1-resistor memory cells (herein referred to as 2T(NMOS)1R memory cells) forming the main array 102. A single 2T(NMOS)1R memory cell is shown in FIG. 2 for simplicity, though it should be understood that the main array 102 will include a plurality of such memory cells in an array or other repeating arrangement.

FIG. 2 also shows a plurality of word lines 120 (referred to herein as WL) and a plurality of bit lines 122 (referred to herein as BL). As shown in FIG. 2, repeaters 112 are arranged along the length of the plurality of word lines 120 within the first memory segment 110 (as well as the other memory segments). These repeaters 112 maintain a voltage level of the word line along its length.

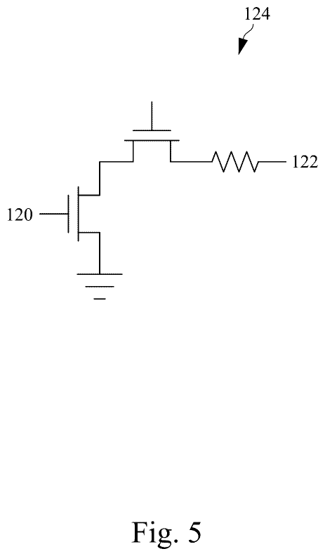

While the symbol shows a 2T(NMOS)1R memory cell as the core component of each of the main arrays, it should be understood that any of a number of memory cell architectures could be used in alternative embodiments, several of which are illustrated with respect to FIGS. 5-8. The plurality of memory cells can be, for example, a plurality of eFuse memory cells as described above.

Memory device 100 can be implemented with various memory cell architectures beyond the basic 2T(NMOS)1R configuration shown in the figures. These architectures include both NMOS and PMOS implementations, with configurations ranging from two-transistor arrangements to single-transistor designs. For example, while the 2T(NMOS)1R memory cell represents one implementation, alternative arrangements such as the 2T(PMOS)1R configuration can be employed to achieve similar functionality with different electrical characteristics.

The flexibility in memory cell architecture extends to various resistor configurations as well. Some implementations may utilize a direct connection to VDD in place of a resistor, while others maintain the traditional resistor arrangement. These variations in memory cell design allow for optimization based on specific performance requirements and manufacturing constraints. The choice between NMOS and PMOS implementations, as well as the decision to use one or two transistors, can be made based on factors such as power consumption, speed requirements, and integration considerations.

In the context of eFuse implementations specifically, the memory cells utilize a narrow strip of conducting material, commonly referred to as a “fuse link,” positioned between two pads that serve as the anode and cathode. The programming process for these eFuse cells involves applying a program current that physically alters the fuse link, changing its resistivity and thereby storing data. This fundamental eFuse structure can be integrated into various memory cell architectures, allowing for flexibility in implementation while maintaining the core functionality of non-volatile memory storage.

The eFuse implementation is particularly valuable in the context of non-volatile memory applications, where data retention is required even when power is removed from the device. This makes eFuse memory cells especially suitable for storing critical information such as lot numbers and security data. The programming process creates a permanent change in the physical structure of the fuse link, ensuring that the stored data remains stable and reliable over time. This characteristic makes eFuse implementations particularly valuable in applications where data permanence is essential.

When implementing these various memory cell architectures, the memory device 100 can utilize transmission gates 104 and repeaters 112 to maintain signal integrity across the memory segments 110. This approach ensures reliable operation regardless of the specific memory cell architecture chosen, allowing for flexibility in design while maintaining robust performance characteristics.

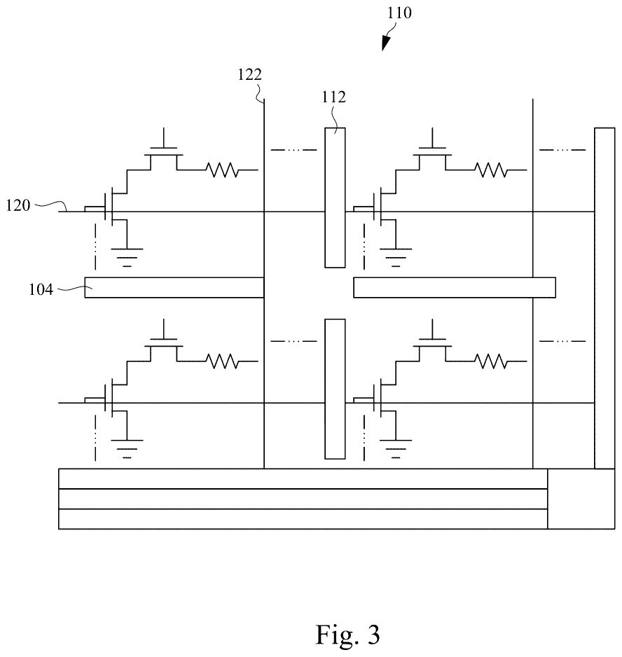

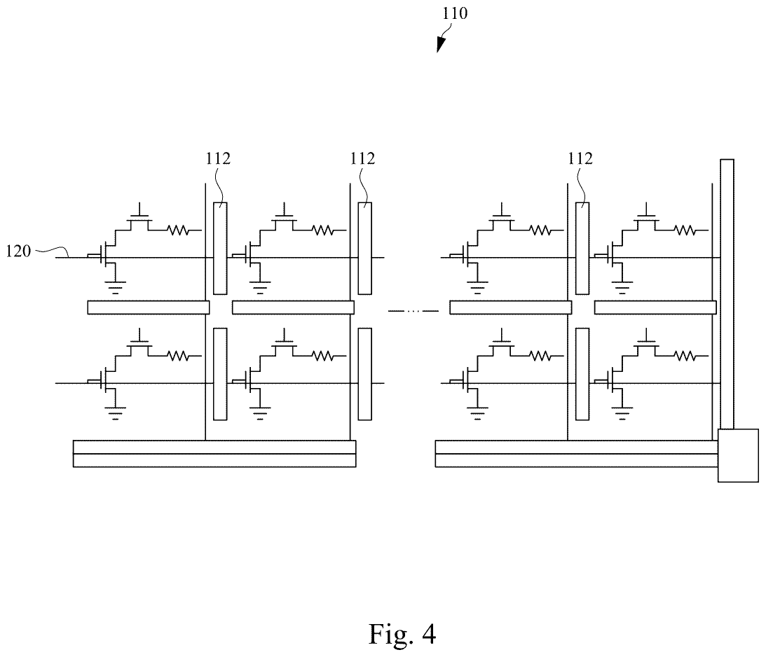

FIGS. 3 and 4 show a contrast between a simple, single-repeater embodiment and a more complex, multi-repeater embodiment.

FIG. 3 shows a memory segment 110 having a single repeater 112 therein. As indicated by the ellipses, there may be multiple 2T(NMOS)1R memory cells arranged on the word line 120 on either side of the repeater 112.

In contrast, FIG. 4 shows a memory segment 110 having a plurality of repeaters 112 therein. In the embodiment of FIG. 4, each of the 2T(NMOS)1R memory cells is separated from adjacent ones of the 2T(NMOS)1R memory cells by a repeater 112. Thus FIG. 4 shows a system in which the input voltage along the word line 120 should be nearly identical because each 2T(NMOS)1R memory cell receives signal that has been voltage-adjusted by a repeater 112.

Of course, it should be understood that while FIG. 3 and FIG. 4 show two extremes, embodiments are contemplated in which there are more than one repeater 112, but not necessarily a repeater 112 corresponding to each individual memory cell. For example, a system could have a pair of repeaters 112, or a repeater 112 every n memory cells, where n is greater than 1. In general, a WL repeater 112 is used to address WL loading and provide programmability and leakage that is similar to a standard structure memory structure.

Local transmission gate circuits (e.g., transmission gates 104) are used to address BL parasitic resistance and achieve performance. For this reason, repeaters 112 are shown only along the word lines 120, and not along the bit lines 122. This configuration provides improved programmability and leakage performance. In a high voltage operation mode, minimum gate length may be adopted.

Some examples use a two transistor/one resistor (2T1R) arrangement with a transmission gate circuit connected to the bit lines 122, and a repeater 112 connected to the word lines 120. One or more repeaters 112 may be connected to memory segments. Other embodiments use a one transistor/one resistor (1T1R) memory cell arrangement. The transistor threshold voltage (VT) of the memory cell transistor(s) may vary in some embodiments. Further, NMOS and PMOS memory cell transistor embodiments are disclosed.

The memory segment 110 can be implemented with varying configurations of repeaters 112 along the word lines 120, as illustrated in FIGS. 3 and 4. In the simpler configuration depicted in FIG. 3, memory segment 110 employs a single repeater 112 positioned centrally along the word line 120. This arrangement allows for multiple 2T(NMOS)1R memory cells to be arranged on either side of the repeater 112, with the repeater serving to maintain signal integrity along the word line.

A more sophisticated implementation is shown in FIG. 4, where memory segment 110 incorporates multiple repeaters 112 in a distributed arrangement along the word line 120. In this configuration, each individual 2T(NMOS)1R memory cell is separated from adjacent memory cells by a dedicated repeater 112. This arrangement ensures that the input voltage remains nearly constant along the entire word line 120, as each memory cell receives a signal that has been freshly adjusted by its corresponding repeater.

Between these two extremes, various intermediate configurations are possible within memory segment 110. For instance, the system could be designed with two repeaters 112, or with repeaters placed at regular intervals corresponding to every nth memory cell, where n represents any number greater than one. This flexibility in repeater placement allows for optimization based on specific design requirements and performance considerations.

The implementation of repeaters 112 specifically along word lines 120, rather than bit lines 122, serves a crucial purpose in addressing word line loading issues while maintaining programmability comparable to standard memory structures. This arrangement works in concert with local transmission gate circuits (transmission gates 104) which are specifically designed to address bit line parasitic resistance and achieve optimal performance. The combination of these elements enables improved programmability and leakage performance, particularly in high voltage operation modes.

The effectiveness of this architecture is particularly evident in ultra-high density memory structures, where the strategic placement of repeaters 112 helps maintain consistent signal strength and integrity throughout the memory segment 110. This approach ensures that voltage levels remain stable and appropriate for proper memory cell operation, regardless of a cell's position along the word line 120.

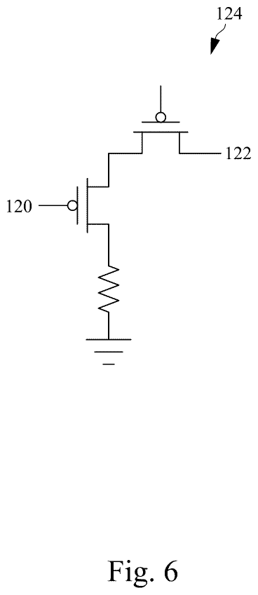

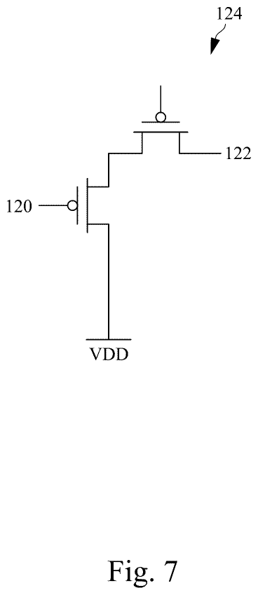

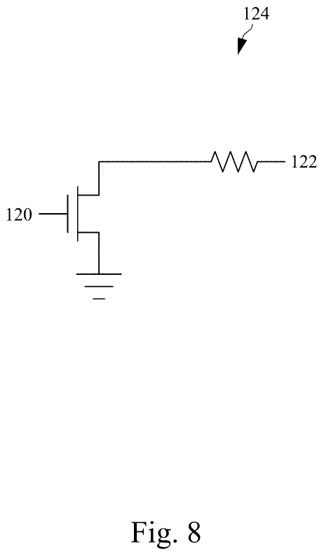

FIGS. 5-8 show some examples of memory cell arrangements that are contemplated in an eFuse environment. FIG. 5 is a circuit diagram of a memory cell 124. Specifically, FIG. 5 shows the 2T(NMOS)1R memory cell 124 that has been described previously with respect to FIGS. 2-4. FIG. 6 shows an alternative memory cell 124 using PMOS architecture, still with two transistors and a resistor (i.e., a 2T(PMOS)1R memory cell). FIG. 7 shows an alternative embodiment of a memory cell 124 in which the resistor is removed and replaced with a direct connection to VDD. FIG. 8 shows an alternative embodiment of a memory cell 124 in which a single transistor is connected to the WL while the bit line is connected to one side of the transistor by a resistor and the other side of the transistor is connected to ground.

The 2T(NMOS)1R memory cell 124, shown in FIG. 5, represents a fundamental architecture that leverages two N-channel Metal Oxide Semiconductor transistors and a single resistor for data storage. This configuration employs one NMOS transistor as the access transistor and another as the storage transistor, with the access transistor connected to the word line for controlling memory cell access and the storage transistor connected to the bit line for data input/output. The resistor helps maintain charge on the storage capacitor, providing enhanced data retention capabilities.

In the 2T(NMOS)1R memory cell shown in FIG. 5, when current is initially applied, the word line 120 activation triggers the access transistor by applying a voltage to its gate terminal. When this transistor turns on, it creates a conductive path between its source and drain terminals, allowing the bit line 122 to connect to the storage node. The voltage applied through the bit line 122 then influences the gate of the storage transistor, while the resistor provides a path to either power supply or ground, depending on the logic state being written. During this process, the storage capacitor begins charging or discharging through the storage transistor, with the current flow determined by the voltage differential between the bit line and the storage node.

An alternative implementation shown in FIG. 6 utilizes PMOS architecture while maintaining the two-transistor and resistor configuration (2T(PMOS)1R). This variation offers different electrical characteristics while maintaining similar functionality to its NMOS counterpart. When implemented in memory device 100, the PMOS configuration can provide unique advantages in terms of power consumption and switching characteristics, particularly when integrated with the word line decoder 108 and bit line decoder 106 systems.

The structure shown in FIG. 6 exhibits distinct current and voltage behaviors compared to the FIG. 5 2T(NMOS)1R configuration. In the 2T(PMOS)1R configuration shown in FIG. 6, the fundamental operation remains similar, but the current flow characteristics differ due to the use of PMOS transistors instead of NMOS transistors. While the NMOS configuration relies on pulling the output low when activated, the PMOS implementation operates by pulling the output high, leading to different voltage swing characteristics during switching operations.

The configuration shown in FIG. 7 represents a significant departure from the FIG. 5 structure by removing the resistor and implementing a direct connection to VDD. This modification alters the current path during both write and read operations, eliminating the resistive element that helps stabilize the voltage at the storage node. Without the resistor's voltage-stabilizing effect, the circuit relies more heavily on the transistors'characteristics to maintain stored charge, potentially affecting both power consumption and data retention characteristics.

FIG. 7 presents a modified architecture where the resistor is eliminated and replaced with a direct connection to VDD. This simplified structure reduces component count while still maintaining essential memory functionality. When incorporated into the larger memory device 100, this configuration can offer advantages in terms of manufacturing simplicity and potentially reduced parasitic effects, while still benefiting from the signal integrity maintenance provided by repeaters 112 along the word lines 120.

The single-transistor configuration shown in FIG. 8 represents a further simplified architecture where a single transistor is connected to the word line, with the bit line connected through a resistor to one side of the transistor while the other side connects to ground. This minimalist approach can be particularly advantageous in ultra-high density memory applications where space efficiency is paramount. When implemented within memory segments 110, this configuration can achieve high integration density while maintaining reliable operation through the strategic placement of repeaters 112.

FIG. 8 presents a simplified single-transistor architecture where the bit line connects to one side of the transistor through a resistor while the other side connects to ground. This configuration's current behavior differs substantially from the FIG. 5 structure, as it relies on a single transistor for both access and storage functions. The current path during write operations flows directly through the resistor to ground, with the voltage level at the storage node determined by the resistance value and the applied bit line voltage.

Each of these memory cell architectures can be effectively integrated into the broader memory device 100 structure, working in conjunction with transmission gates 104 and repeaters 112 to maintain signal integrity. The choice between these configurations can be optimized based on specific application requirements, such as power consumption, speed requirements, and integration density needs. The flexibility of memory device 100 to accommodate these various cell architectures while maintaining robust performance characteristics through its repeater and transmission gate infrastructure makes it particularly versatile for different implementation scenarios.

The reliability and manufacturing considerations for these memory cell architectures vary significantly based on their implementation. In the 2T(NMOS)1R configuration, the use of two NMOS transistors provides robust data storage capabilities through the combination of an access transistor connected to the word line and a storage transistor connected to the bit line. This architecture's reliability is enhanced by the resistor's role in maintaining charge on the storage capacitor, which is particularly important for data retention in high-density applications.

The 2T(PMOS)1R implementation offers distinct manufacturing advantages in certain scenarios, particularly when considering power consumption characteristics. The PMOS configuration can be especially beneficial when integrated with word line decoder and bit line decoder systems, though it requires careful consideration of voltage level translation between different circuit domains to maintain reliable operation.

In ultra-high density memory structures, the choice between NMOS and PMOS implementations becomes particularly critical due to parasitic resistance and leakage concerns. The NMOS implementation typically offers better programming performance due to its inherent characteristics, while PMOS configurations may provide advantages in terms of leakage current control. These considerations become especially important when dealing with longer bit lines and word lines, where signal degradation can impact programming efficiency.

Manufacturing yield considerations are closely tied to the complexity of each architecture. The simplified single-transistor configuration can potentially offer higher manufacturing yields due to its reduced component count, though this must be balanced against potential reliability concerns. In contrast, the two-transistor configurations, while more complex to manufacture, can provide enhanced stability through their dual-transistor control scheme.

Long-term stability in high-density applications is particularly influenced by the presence of repeaters and transmission gates in the overall architecture. These components help maintain signal integrity regardless of the chosen transistor implementation, though their effectiveness may vary depending on whether NMOS or PMOS configurations are used. The strategic placement of repeaters along word lines becomes especially critical in maintaining consistent performance across large memory arrays, regardless of whether NMOS or PMOS implementations are chosen.

The parasitic resistance considerations in ultra-high density structures particularly affect programming current capabilities, with both NMOS and PMOS implementations requiring careful design optimization to maintain reliable programming performance. This is especially relevant when considering the Ron value of program devices, which directly impacts the efficiency of programming operations and overall reliability of the memory structure.

The power consumption characteristics between 2T(NMOS)1R and 2T(PMOS)1R memory cell 124 configurations present important trade-offs in memory device 100 operation. In the 2T(NMOS)1R configuration, the memory cell utilizes one NMOS transistor as the access transistor and another as the storage transistor, with the access transistor connected to word line 120 and the storage transistor connected to bit line 122. This arrangement affects power consumption particularly during data retention, where the resistor helps maintain charge on the storage capacitor.

The 2T(NMOS)1R configuration's power consumption is particularly relevant during write operations, where word line 120 is activated to turn on the access transistor, allowing bit line 122 to drive the storage node. During this process, power is consumed as voltage corresponding to logic states charges or discharges the storage capacitor through the storage transistor. The resistor's role in stabilizing the voltage at the storage node impacts overall power consumption during active operations.

For the 2T(PMOS)1R configuration, the power characteristics differ primarily due to the inherent properties of PMOS transistors. This configuration becomes particularly relevant when considering the interaction with word line decoder 108 and bit line decoder 106 systems, especially in scenarios where voltage level translation between different circuit domains is required. The PMOS implementation may offer advantages in terms of standby power consumption due to its inherent characteristics.

In both configurations, power consumption is significantly influenced by the presence of parasitic resistance and leakage currents, particularly in ultra-high density memory structures. The parasitic resistance along bit lines 122 can impact programming current capabilities, which directly affects active power consumption during write operations. This consideration becomes especially important when dealing with the Rₒₙ value of program devices, as it impacts the efficiency of programming operations and overall power consumption during active states.

The implementation of repeaters 112 along word lines 120 affects power consumption in both architectures, as these components help maintain signal integrity but introduce additional power requirements. This is particularly relevant in larger memory arrays where signal degradation would otherwise require higher power consumption to maintain reliable operation. The strategic placement of repeaters 112 helps optimize power consumption while ensuring consistent performance across memory segments 110.

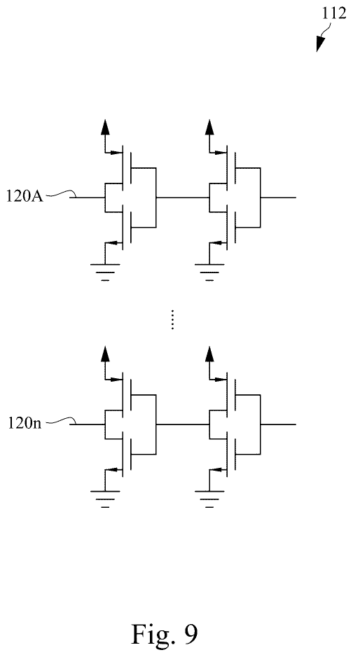

FIG. 9 shows the circuitry of a repeater 112 according to one embodiment. Repeater 112 is connected to a plurality of word lines 120. These individual word lines are numbered word line 120A through 120n.

Repeater 112 as shown in FIG. 9 is used to amplify or restore signals in digital circuits such as along the word lines 120A-120n. The particular architecture of repeater 112 of FIG. 9 is constructed using two CMOS inverter stages in a series configuration. Each inverter stage consists of a PMOS transistor and an NMOS transistor. The top transistor in each inverter stage is a PMOS transistor. The sources for the PMOS transistors are connected to the supply voltage (VDD), and their drains are connected to the output of the inverter stage. The gates of the PMOS transistors are connected to the input signal of the inverter stage. The bottom transistors in each inverter stage are NMOS transistors. Their sources are connected to the ground (GND), and their drains are connected to the output of the inverter stage. The gates of the NMOS transistors are also connected to the input signal of the inverter stage.

The input signal (provided by the word lines 120A-120n) is fed into the gate terminals of both the PMOS and NMOS transistors of the first inverter. When the input is high, the PMOS transistor is turned off, and the NMOS transistor is turned on, pulling the output of this stage to ground, producing a low output. Conversely, when the input is low, the PMOS transistor is turned on, and the NMOS transistor is turned off, pulling the output of this stage to VDD, producing a high output.

The output of the first inverter stage serves as the input to the second inverter stage. This stage functions similarly: if the input to the second stage is high, the output will be low, and if the input is low, the output will be high. Therefore, the second inverter stage inverts the signal again, restoring it to its original logic level but with refreshed signal strength.

The repeater 112 circuit as a whole amplifies the signal input from the word lines 120A-120n as it passes from the input to the output. The two inverter stages cooperate such that any degradation or attenuation of the signal is corrected, maintaining the integrity and strength of the signal. This is particularly useful in long wire runs of the word lines 120A-120n within integrated circuits where signal degradation due to resistance and capacitance can be significant. By placing repeaters at intervals along the word lines 120A-120n, the signal can be kept strong and reliable, ensuring proper operation of the memory cells, the memory segments, and the memory device.

It should be understood that there are various alternative architectures that could be used to form repeater 112. For example, repeater 112 could take the form of a Standard Threshold Voltage repeater, a Low Threshold Voltage repeater, a High Threshold Voltage repeater, and a Mix Threshold Voltage repeater. Not all such repeaters need be a two-stage inverter 112 such as the one shown in FIG. 9. Though other repeater architectures are not specifically depicted herein, many such alternative designs are known and would be usable in lieu of the specific implementation shown in FIG. 9.

Several alternative repeater architectures could be implemented within memory device 100 to maintain signal integrity along word lines 120. A Standard Threshold Voltage repeater represents one alternative approach, where the threshold voltages of both PMOS and NMOS transistors are maintained at standard levels for the given process technology. This configuration provides a balanced approach to signal restoration while maintaining typical power consumption characteristics.

Low Threshold Voltage repeaters offer another alternative architecture, where the threshold voltages of the transistors are reduced compared to standard levels. This configuration can provide faster switching speeds and improved performance in low-voltage operations, though it may come with increased leakage current considerations. This trade-off becomes particularly relevant when implementing repeaters 112 in ultra-high density memory structures.

High Threshold Voltage repeaters present a third alternative, utilizing transistors with elevated threshold voltages. This configuration can be particularly advantageous in scenarios where minimizing leakage current is a priority, though it may result in slightly slower switching speeds. The higher threshold voltages can help maintain signal integrity while reducing standby power consumption along word lines 120.

Mix Threshold Voltage repeaters represent a hybrid approach, combining transistors with different threshold voltages within the same repeater structure. This configuration allows for optimization of both performance and power consumption characteristics, potentially providing advantages in specific memory segment 110 implementations where varying performance requirements exist along different sections of the word lines 120.

While these alternative repeater architectures differ from the two-stage inverter implementation detailed in the figures, they all serve the fundamental purpose of maintaining signal integrity along word lines 120 within memory device 100. The choice between these different repeater architectures can be optimized based on specific requirements for power consumption, switching speed, and leakage current considerations in the overall memory architecture.

The different repeater architectures have distinct impacts on the timing characteristics of word line 120 signals. The standard two-stage inverter implementation of repeater 112 processes signals by having each inverter stage respond to input changes, with the PMOS transistor turning off and NMOS transistor turning on for high inputs, and vice versa for low inputs. This configuration provides a baseline for signal propagation and restoration along the word lines 120.

Standard Threshold Voltage repeaters maintain typical rise and fall times based on the process technology's standard threshold voltages. When implemented along word lines 120, these repeaters provide consistent signal amplification and restoration, ensuring that the voltage signal maintains sufficient strength to reliably turn on the access transistors of memory cells along the entire length of the word line.

Low Threshold Voltage repeaters can achieve faster switching speeds due to their reduced threshold voltages, potentially decreasing both rise time and fall time of signals along word lines 120. This improved switching speed can be particularly beneficial in memory segments 110 where rapid access times are crucial. However, this enhanced speed must be balanced against potential increases in leakage current, which could affect the stability of voltage levels between switching events.

High Threshold Voltage repeaters typically exhibit longer rise and fall times due to their elevated threshold voltages. While this may result in increased propagation delay along word lines 120, the higher thresholds provide better noise immunity and more stable voltage levels. This characteristic becomes particularly important when dealing with signal integrity in larger memory arrays where noise and signal degradation are significant concerns.

Mix Threshold Voltage repeaters offer the ability to optimize different aspects of signal timing by combining transistors with varying threshold voltages. This architecture can be particularly effective in managing the trade-off between switching speed and signal stability, allowing for customized timing characteristics based on specific requirements of different sections within memory segments 110.

The placement and architecture of these repeaters significantly impact the overall timing characteristics of memory device 100, particularly in scenarios where word lines 120 span multiple memory segments 110. The strategic positioning of repeaters 112 helps ensure that signals remain robust and timing characteristics remain within acceptable parameters, thereby enhancing the speed and accuracy of memory access operations across the entire array.

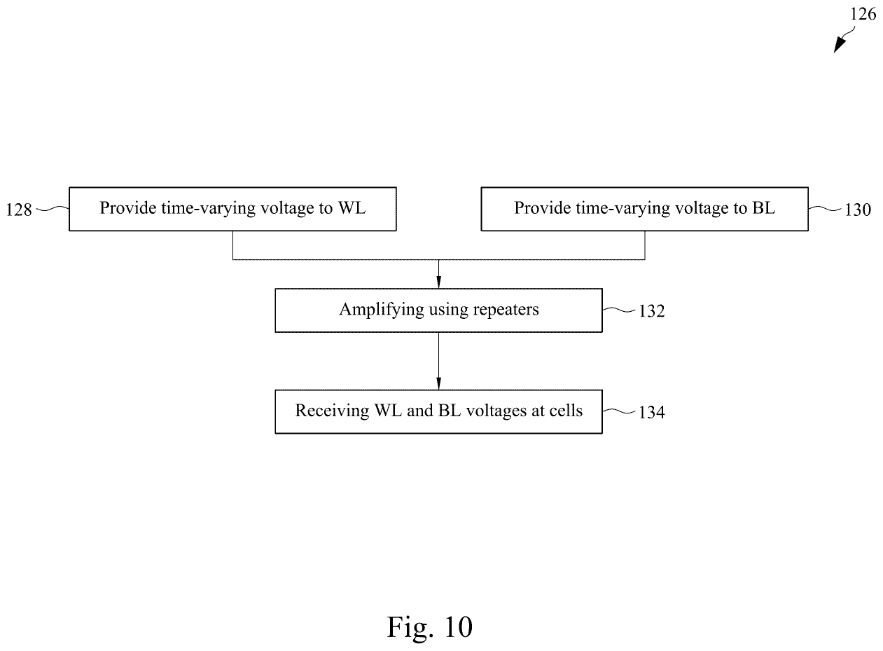

FIG. 10 is a flowchart depicting a method 126 for operating a device according to either of FIG. 1 or 2 including or a memory segment as shown in FIGS. 3 and 4.

Method 126 including providing time-varying voltage to a WL at 128 and providing time-varying voltage to a BL at 130. As a practical matter, in any memory device (e.g., memory device 100 of FIGS. 1 and 2) there will be a plurality of memory cells, such that providing time-varying voltage to a WL at 128 will include sending time-varying voltage to a large number of WLs. This can be done, for example, by routing signal to a plurality of WLs 120 by a word line decoder 108 as shown and described above with respect to FIGS. 1 and 2. Similarly, at 130 a plurality of BLs can be provided with time-varying voltage using the structures shown and described with respect to bit line decoder 106 and bit lines 122 of FIGS. 1 and 2.

At 132, repeaters are used to amplify the signal provided to the WLs at 128. As described above, using repeaters to amplify the signal to the WLs combats parasitic signal loss and improves memory device function. In the embodiments depicted with respect to FIGS. 1-4, for example, repeaters 112 were used to amplify the signal provided to the WLs. In various embodiments, the amplification can be provided by combinations of NMOS and PMOS transistors as depicted in FIG. 9, among other known varieties of repeater.

At 134, the WL and BL voltages are received at each of the memory cells. Many of the memory cells that receive WL and BL voltages will be receiving amplified signal at the WL terminal, because the signal will have been amplified by a repeater at 132. As such, the deterioration in signal quality that could otherwise have occurred in a conventional device is obviated.

The structures and methods described in the documents address several critical challenges in memory device design, particularly focusing on signal integrity and programming performance in large memory arrays. The fundamental problem stems from the inherent limitations of longer word lines (WL) and bit lines (BL) in memory circuits, which face increased resistance and capacitance, leading to signal integrity challenges including voltage drop, noise, and crosstalk. These issues can significantly disrupt proper data reading and writing operations, while also increasing power consumption as more energy is required to drive signals through longer lines.

A specific challenge addressed is the degradation of programming performance in ultra-high density memory structures due to higher parasitic resistance in the bit lines. This parasitic resistance impedes current flow, affecting the efficiency and speed of programming memory cells. Additionally, longer word line paths can result in increased leakage, creating a trade-off between achieving higher program current capabilities and managing leakage current in the word line path.

The solution implements a sophisticated combination of repeaters and transmission gates to maintain signal integrity across the memory array. Repeater circuits are strategically placed along the word lines to amplify or restore signals as they travel, counteracting the degradation that naturally occurs due to resistance and capacitance in long conductive paths. These repeaters ensure that signals maintain sufficient strength to reliably activate memory cells, regardless of their position along the word line.

The architecture further addresses these challenges through the implementation of transmission gates between memory segments, which help manage bit line parasitic resistance and achieve optimal performance. This approach is particularly effective in ultra-high density memory structures where maintaining consistent signal strength and programming capability is crucial. The combination of repeaters on word lines and transmission gates on bit lines provides a comprehensive solution to signal degradation issues while maintaining programmability comparable to standard memory structures.

The solution also accommodates various memory cell architectures, including 2T(NMOS)1R, 2T(PMOS)1R, and simplified single-transistor configurations, allowing for flexibility in implementation while maintaining robust performance characteristics. This versatility enables optimization based on specific application requirements while ensuring reliable operation through the strategic placement of repeaters and transmission gates. The architecture effectively balances the trade-offs between signal integrity, power consumption, and overall circuit complexity, providing a practical solution for high-density memory applications.

The implementation of level shifters within the architecture addresses the challenge of voltage translation between different domains of the circuit, ensuring proper communication between memory cells and peripheral circuitry. This aspect of the solution is particularly important when different parts of the memory circuit operate at different voltage levels, helping to prevent data corruption and ensure reliable operation across the entire memory device.

According to a first aspect, a device is disclosed comprising a first memory segment coupled to a first decoder through a first transmission gate; a second memory segment separated from the first memory segment by a second transmission gate and coupled to the first decoder through the second transmission gate; a third memory segment coupled to the first decoder by a third transmission gate; and a repeater circuit coupled between the first memory segment and the third memory segment through a plurality of word lines that are coupled to a second decoder.

According to a second aspect, a memory array is disclosed comprising a plurality of word lines; a plurality of bit lines; a plurality of memory cells, each of the plurality of memory cells coupled to a corresponding one of the plurality of word lines and a corresponding one of the plurality of bit lines; and a plurality of repeaters arranged along the plurality of word lines such that each of the plurality of memory cells is separated from an adjacent one of the plurality of memory cells along its corresponding word line by at least one of the plurality of repeaters.

According to a third aspect, a method for operating a memory segment is disclosed, the method comprising providing a time-varying voltage signal to a plurality of word lines via a word line decoder; providing a time-varying voltage signal to a plurality of bit lines via a bit line decoder; receiving, at each of a plurality of memory cells, the time-varying voltage corresponding to one of the plurality of word lines and the time-varying voltage corresponding to one of the plurality of bit lines; and amplifying the time-varying voltage on each of the plurality word lines at at least one repeater, the at least one repeater arranged along each of the plurality of word lines such that each of the plurality of memory cells is separated from an adjacent one of the plurality of memory cells along its corresponding word line by the at least one repeater.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A device, comprising:
a first memory segment coupled to a first decoder through a first transmission gate;
a second memory segment separated from the first memory segment by a second transmission gate and coupled to the first decoder through the second transmission gate;
a third memory segment coupled to the first decoder by a third transmission gate; and
a repeater circuit coupled between the first memory segment and the third memory segment through a plurality of word lines that are coupled to a second decoder.

2. The device of claim 1, wherein each memory segment includes a plurality of eFuse memory cells.

3. The device of claim 2, wherein each of the eFuse memory cells includes a two transistor/one resistor (2T/1R) arrangement.

4. The device of claim 2, wherein each of the eFuse memory cells includes a one transistor/one resistor (1T/1R) arrangement.

5. The device of claim 1, wherein the first transmission gate and the third transmission gate are two portions of a single transmission gate.

6. The device of claim 1, the repeater circuit comprising a two-stage inverter including a first stage having a PMOS and an NMOS transistor and a second stage having a PMOS and an NMOS transistor.

7. A memory array comprising:
a plurality of word lines;
a plurality of bit lines;
a plurality of memory cells, each of the plurality of memory cells coupled to a corresponding one of the plurality of word lines and a corresponding one of the plurality of bit lines; and
a plurality of repeaters arranged along the plurality of word lines such that each of the plurality of memory cells is separated from an adjacent one of the plurality of memory cells along its corresponding word line by at least one of the plurality of repeaters.

8. The memory array of claim 7, further comprising a word line decoder coupled to the plurality of word lines and configured to shift a voltage level of the word lines.

9. The memory array of claim 7, further comprising a bit line decoder coupled to the plurality of bit lines and configured to shift a voltage level of the bit lines.

10. The memory array of claim 7, wherein the memory array comprises a plurality of memory segments, each memory segment of the plurality of memory segments comprising a subset of the plurality of memory cells.

11. The memory array of claim 10, wherein each of the plurality of memory segments includes more than one pair of the plurality of repeaters.

12. The memory array of claim 7, wherein each repeater of the plurality of repeaters is selected from the group consisting of: a Standard Threshold Voltage repeater, a Low Threshold Voltage repeater, a High Threshold Voltage repeater, and a Mix Threshold Voltage repeater.

13. The memory array of claim 7, wherein each of the plurality of memory cells is one of a 2T(NMOS)1R memory cell and a 2T(PMOS)1R memory cell.

14. The memory array of claim 7, the plurality of repeaters each comprising a two-stage inverter including a first stage having a PMOS and an NMOS transistor and a second stage having a PMOS and an NMOS transistor.

15. A method, comprising:
providing a time-varying voltage signal to a plurality of word lines via a word line decoder;
providing a time-varying voltage signal to a plurality of bit lines via a bit line decoder;
receiving, at each of a plurality of memory cells, the time-varying voltage corresponding to one of the plurality of word lines and the time-varying voltage corresponding to one of the plurality of bit lines; and
amplifying the time-varying voltage on each of the plurality word lines at at least one repeater, the at least one repeater arranged along each of the plurality of word lines such that each of the plurality of memory cells is separated from an adjacent one of the plurality of memory cells along its corresponding word line by the at least one repeater.

16. The method of claim 15, wherein the memory segment comprises a subset of the plurality of memory cells of a memory array having multiple memory segment, and wherein each of the multiple memory segments is provided with a corresponding time-varying voltage signal to its corresponding plurality of bit lines and its corresponding plurality of word lines.

17. The method of claim 15, wherein amplifying comprises arranging a plurality of repeaters along each of the plurality of word lines.

18. The method of claim 15, wherein the at least one repeater is selected from the group consisting of: a Standard Threshold Voltage repeater, a Low Threshold Voltage repeater, a High Threshold Voltage repeater, and a Mix Threshold Voltage repeater.

19. The method of claim 15, wherein each of the plurality of memory cells is one of a 2T(NMOS)1R memory cell and a 2T(PMOS)1R memory cell.

20. The method of claim 15, the at least one repeater comprising a two-stage inverter including a first stage having a PMOS and an NMOS transistor and a second stage having a PMOS and an NMOS transistor.
